(19) United States
(12) Patent Application Publication
(10) Pub. No.: US 2016/0071797 A1
(43) Pub. Date: Mar. 10, 2016

(54) EFUSE STRUCTURE WITH STRESSED LAYER

(71) Applicant: SEMICONDUCTOR MANUFACTURING INTERNATIONAL (SHANGHAI) CORPORATION, Shanghai (CN)

(72) Inventor: ZHENGHAO GAN, Shanghai (CN)

(21) Appl. No.: 14/822,887

(22) Filed: Aug. 10, 2015

(30) Foreign Application Priority Data
Sep. 9, 2014 (CN) 201410455030.1

(51) Int. Cl. H01L 23/525; H01L 23/528; H01L 23/532

(52) U.S. Cl. CPC H01L 23/5256; H01L 23/5329; H01L 23/53271; H01L 23/53209; H01L 23/53261; H01L 23/528

(57) ABSTRACT

An electrically programmable fuse device includes an anode, a cathode, a fuse link connecting the anode and the cathode, a compressive stress layer on the anode, and a tensile stress layer on the cathode. Because of the compressive stress layer on the anode and a tensile stress layer on the cathode, the programming speed of the electrically programmable fuse device is shorter in relation to conventional electrically programmable fuse devices.

### CROSS-REFERENCES TO RELATED APPLICATIONS

This application claims priority to Chinese patent application No. 201410455030.1, filed on Sep. 9, 2014, the content of which is incorporated herein by reference in its entirety.

### BACKGROUND OF THE INVENTION

The present invention relates to a semiconductor structure and method of manufacture, and more particularly to electrically programmable fuse structures for an integrated circuit.

Along with the benefits of compatibility with CMOS logic processes and ease of use, electrically programmable fuses (eFuses) can be advantageously used as a one-time programmable (OTP) memory in a wide variety of applications.

FIGS. 1A and 1B are plan views of two typical structures of an eFuse device according to the prior art. The two types of eFuse structures include an anode 101, a cathode 102, and a fuse link portion (alternatively referred to as fuse link or efuse link) 103. Anode 101 and cathode 102 are also referred to as eFuse heads. The main difference between the two eFuse types of FIGS. 1A and 1B is the different shape of the eFuse head. The eFuse head shown in FIG. 1B is rectangular shaped whereas the eFuse head shown in FIG. 1A is polygonal shaped having a tapered portion that narrows toward the eFuse link 103. Typically, the different shape of the eFuse heads of FIGS. 1A and 1B has the same cross-section. FIG. 1C is a cross-sectional view of FIGS. 1A or 1B taken along the line AA′. As shown in FIG. 1C, the anode, the cathode, and the fuse link portion are formed of a silicide layer 202 disposed on a polysilicon layer 201.

In practical applications, there is a need for a fuse structure that can be programmed at a low voltage and low current while keeping the high resistance of the fuse unchanged after the fuse link portion has been burnt (melted). Thus, an eFuse structure has been proposed in the semiconductor industry, as shown in FIG. 2. FIG. 2 is a cross-sectional view of an eFuse structure of the prior art. The eFuse structure includes a compressive stress layer 203 disposed on the anode and cathode of the structures of FIGS. 1A and 1B. The compressive stress layer 203 applies compressive stress to the polysilicon layer 201 and silicide layer 202 so that they are in a tensile stress state. The tensile stress in the anode region can neutralize the reverse compressive stress generated by the electron mobility, therefore, the melted polycrystalline silicon and silicide can easily move from the cathode to the anode through electrons. Thus, the compressive stress layer 203 may enhance void nucleation and improve the programming resistance and stability of the eFuse device.

However, the eFuse structure of FIG. 2 does not satisfy the fast programming requirements in certain applications. Therefore, there is a need for a novel eFuse device structure that can be programmed at lower programming voltage and current while maintaining a constant resistance after programming.

### BRIEF SUMMARY OF THE INVENTION

Embodiments of the present invention provide an eFuse device, integrated circuit, and electronic device that include an electrically programmable fuse device having a faster programming speed than the conventional eFuse device to reduce the required programming time.

In one embodiment, an electrically programmable fuse device includes an anode, a cathode, a fuse link connecting the anode and the cathode, a compressive stress layer on the anode, and a tensile stress layer on the cathode.

In one embodiment, the compressive stress layer and the tensile stress layer extend on a surface of the fuse link.

In one embodiment, the compressive stress layer and the tensile stress layer are adjacent to each other.

In one embodiment, the compressive stress layer includes a compressive stress silicon nitride material, and the tensile stress layer comprises a tensile stress silicon nitride material.

In one embodiment, the compressive stress layer and the tensile stress layer serve as an etch stop layer for forming a contact hole.

In one embodiment, the anode, the cathode, and the fuse link each include a polysilicon layer and a silicide layer on the polysilicon layer.

In one embodiment, the silicide layer includes at least one of nickel silicide, titanium silicide, cobalt silicide, tantalum silicide, and platinum silicide.

In one embodiment, the anode and the cathode have the same shape, which can be a rectangle, or a rectangle and an isosceles trapezoid.

In one embodiment, the shape of the anode and the cathode is a polygon having a portion tapering toward the fuse link.

In one embodiment, the compressive stress layer applies tensile stress to the anode, and the tensile stress layer applies compressive stress to the cathode. The tensile stress compensates the compressive reverse stress from a dielectric layer. The compressive stress slows down atom migration from the cathode toward a middle portion of the fuse link.

Embodiments of the present invention also provide an integrated circuit having an electrically programmable fuse device. The electrically programmable fuse device includes an anode, a cathode, a fuse link connecting the anode and the cathode, a compressive stress layer on the anode, and a tensile stress layer on the cathode.

Embodiments of the present invention also provide an electronic device including an integrated circuit and an electronic component coupled to the integrated circuit. The integrated circuit includes an electrically programmable fuse device that has an anode, a cathode, a fuse link connecting the anode and the cathode, a compressive stress layer on the anode, and a tensile stress layer on the cathode.

The following description, together with the accompanying drawings, will provide a better understanding of the nature and advantages of the claimed invention.

### BRIEF DESCRIPTION OF THE DRAWINGS

FIGS. 1A and 1B are plan views illustrating two structures of an eFuse device according to the prior art;

FIG. 1C is a cross-sectional view illustrating the eFuse structure of FIGS. 1A and 1B;

FIG. 2 is a cross-sectional view illustrating another structure of an eFuse device according to the prior art;

FIG. 3A is a plan view of an eFuse device according to an embodiment of the present invention;

FIG. 3B is a plan view of an eFuse device according to another embodiment of the present invention;

FIG. 3C is a cross-sectional view illustrating an exemplary structure of an eFuse device according to an embodiment of the present invention;

FIG. 4 is a schematic diagram illustrating the operation principle of a reverse stress of an electromigration process of an eFuse;

FIG. 5A is a schematic diagram illustrating the programming principle of an eFuse device according to an embodiment of the present invention; and

FIG. 5B is another schematic diagram illustrating the programming principle of an eFuse device according to an embodiment of the present invention.

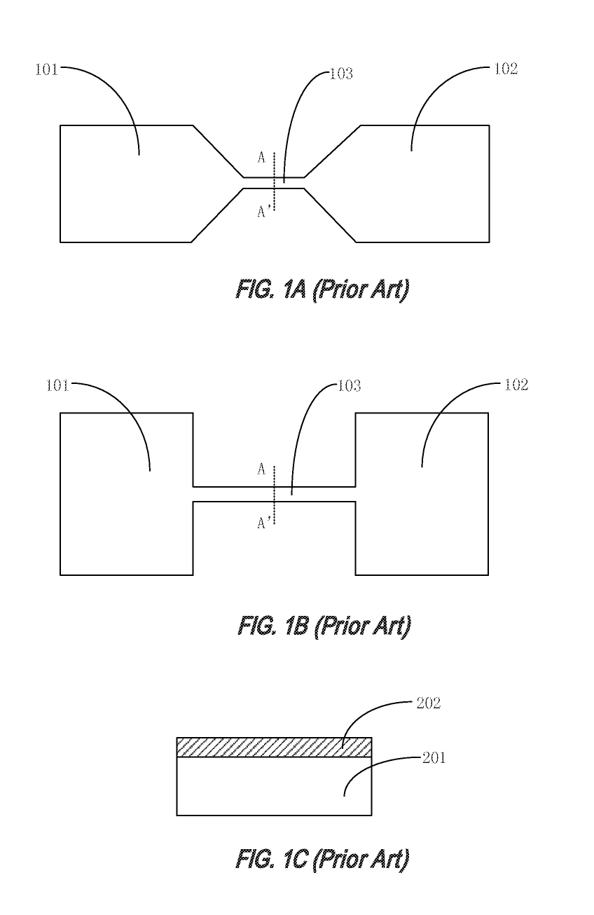

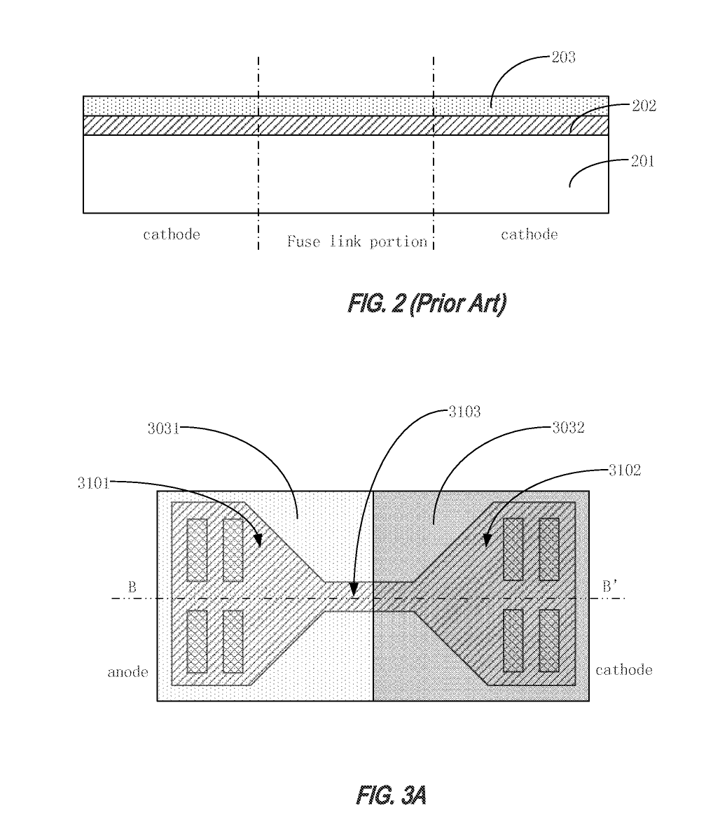

### DETAILED DESCRIPTION OF THE INVENTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

It should be understood that the drawings are not drawn to scale, and similar reference numbers are used for representing similar elements. Embodiments of the invention are described herein with reference to cross-section illustrations that are schematic illustrations of idealized embodiments (and intermediate structures) of the invention. The thickness of layers and regions in the drawings may be exaggerated relative to each other for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

It will be understood that, when an element or layer is referred to as “on,” “disposed on,” “adjacent to,” “connected to,” or “coupled to” another element or layer, it can be disposed directly on the other element or layer, adjacent to, connected or coupled to the other element or layer, or intervening elements or layers may also be present. In contrast, when an element is referred to as being “directly on,” directly disposed on,” “directly connected to,” or “directly coupled to” another element or layer, there are no intervening elements or layers present between them. It will be understood that, although the terms “first,” “second,” “third,” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Relative terms such as “under,” “below,” “underneath,” “over,” “on,” “above,” “bottom,” and “top” are used herein to described a relationship of one element, layer or region to another element, layer or region as illustrated in the figures. It will be understood that these terms are intended to encompass different orientations of the structure in addition to the orientation depicted in the figures. For example, if the device shown in the figures is flipped, the description of an element being “below” or “underneath” another element would then be oriented as “above” the other element. Therefore, the term “below,” “under,” or “underneath” can encompass both orientations of the device. Because devices or components of embodiments of the present invention can be positioned in a number of different orientations (e.g., rotated 90 degrees or at other orientations), the relative terms should be interpreted accordingly.

The terms “a”, “an” and “the” may include singular and plural references. it will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof Furthermore, as used herein, the words “and/or” may refer to and encompass any possible combinations of one or more of the associated listed items.

The use of the terms first, second, etc. do not denote any order, but rather the terms first, second, etc. are used to distinguish one element from another. Furthermore, the use of the terms a, an, etc. does not denote a limitation of quantity, but rather denote the presence of at least one of the referenced items.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

The present invention will now be described more fully herein after with reference to the accompanying drawings, in which preferred embodiments of the invention are shown. This invention may, however, be embodied in many different forms and should not be construed as limited by the embodiments set forth herein. Rather, these embodiments are provided so that this disclosure will be thorough and complete, and will fully convey the scope of the invention to those skilled in the art.

### Embodiment 1

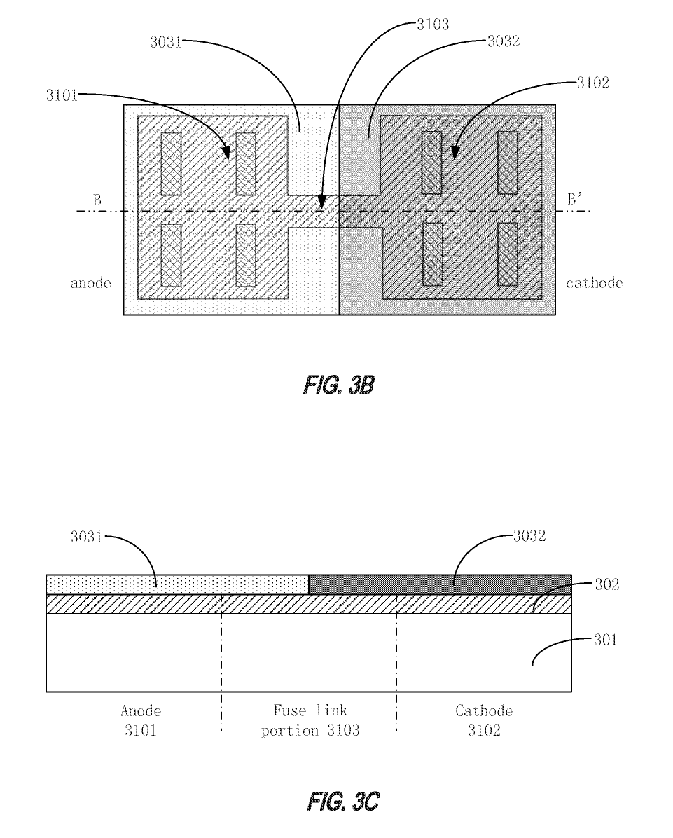

Referring to FIGS. 3A, 3B and 3C, an electrically programmable fuse (eFuse) device will be described. FIG. 3A is a plan view of an eFuse device according to an embodiment of the present invention. FIG. 3B is a plan view of an eFuse device according to another embodiment of the present invention. FIG. 3C is a cross-sectional view illustrating an exemplary structure of an eFuse device taken along the line BB′ of FIGS. 3A and 3B.

As shown in FIGS. 3A, 3B and 3C, the eFuse device may include a polycrystalline silicon layer 301 and a silicide layer 302 disposed on polycrystalline silicon layer 301.

Polycrystalline silicon layer 301 and silicide layer 302 form an anode 3101, a cathode 3102, and a fuse link portion 3103 connecting anode 3101 and cathode 3102. The eFuse device also includes a compressive stress layer 3031 disposed on anode 3101 and covering anode 3101 and a tensile stress layer 3032 disposed on cathode 3102 and covering cathode 3102.

Compressive stress layer 3031 covering anode 3101 and tensile stress layer 3032 covering cathode 3102 may extend on fuse link portion 3103 to be adjacent to (in contact with) each other, as shown in FIGS. 3A, 3B and 3C.

In an embodiment, compressive stress layer 3031 covering anode 3101 and tensile stress layer 3032 covering cathode 3102 may extend on fuse link portion 3103 but are not adjacent to (have no contact with) each other. In another embodiment, compressive stress layer 3031 covering anode 3101 and tensile stress layer 3032 covering cathode 3102 may not extend on fuse link portion 3103. In yet another embodiment, only one of compressive stress layer 3031 covering anode 3101 and tensile stress layer 3032 covering cathode 3102 may extend on fuse link portion 3103. Of course, compressive stress layer 3031 covering anode 3101 and tensile stress layer 3032 covering cathode 3102 may have other positional relationships other than the one described above.

In the embodiment, anode 3101 and cathode 3102 may be referred to as the eFuse head. Two different shapes of an eFuse head are shown in FIGS. 3A and 3B. In FIG. 3A, the eFuse head has a polygonal shape with a portion tapering toward fuse link portion 3103. In an embodiment, the polygonal shape includes a rectangular portion and an isosceles trapezoid portion. In FIG. 3B, the eFuse head has a rectangular shape. Of course, the eFuse head can have other shapes.

FIG. 3C is a cross-sectional view of the structure of FIG. 3A or 3B taken along the line BB′.

In the embodiment, polysilicon layer 301 may be made of polycrystalline silicon. Silicide layer 302 may be made of nickel silicide, titanium silicide, cobalt silicide, tantalum silicide, platinum silicide, or other suitable materials. Compressive stress layer 3031 covering anode 3101 may be formed of compressive stress silicon nitride or other suitable materials. Tensile stress layer 3032 covering cathode 3102 may be formed of tensile stress silicon nitride or other suitable materials.

Compressive stress layer 3031 and tensile stress layer 3032, in addition to applying stress to the anode and cathode, can also serve as an etch stop layer for forming contact holes in the process of forming the contact holes and as a protection layer for the anode and cathode.

Furthermore, in addition to polysilicon layer 301 and silicide layer 302, anode 3101, cathode 3102 and fuse link portion 3103 can also be formed using other structures and materials, which are not described herein for the sake of brevity.

In accordance with the eFuse device of the present invention, promoting electron mobility in anode 3101 and demoting electron mobility in cathode 3102 can be achieved by covering the anode with compressive stress layer 3031 and the cathode with tensile stress layer 3032, so that the eFuse device can have a faster programming speed.

It is understood that the eFuse device, in accordance with the present invention, may include additional layers covering the compressive stress layer and the tensile stress layer and other layers below the anode, the cathode and the fuse link portion.

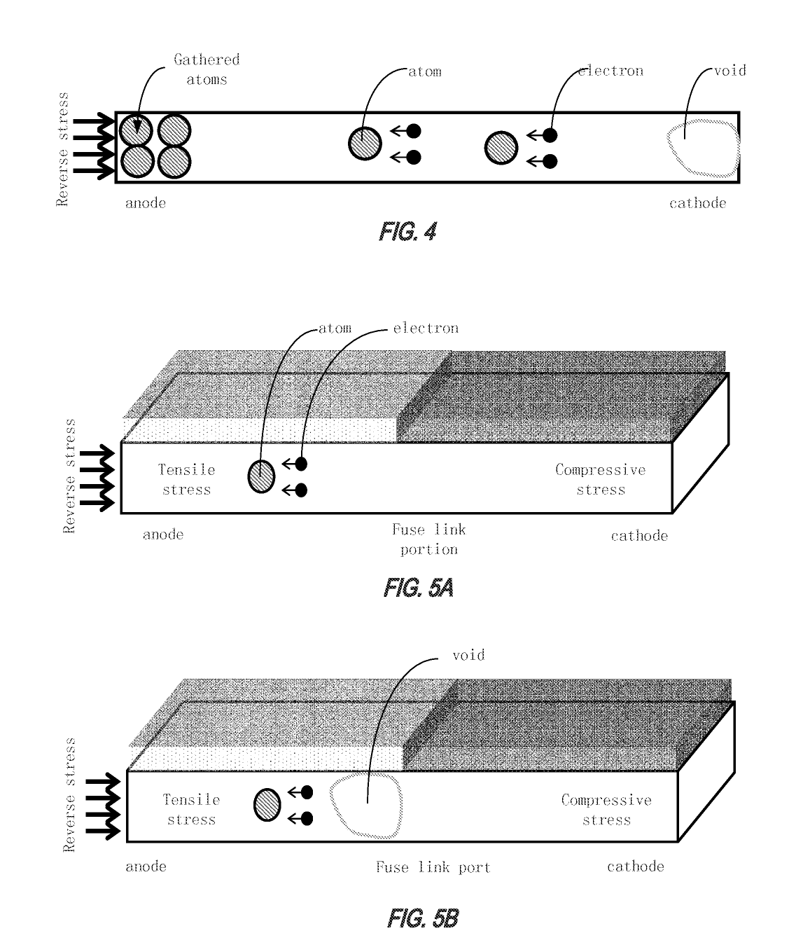

The operation principle of compressive stress layer 3031 and tensile stress layer 3032 of the eFuse device according to the present invention will be explained, with reference to FIG. 4, FIG. 5A and FIG. 5B. FIG. 4 is a cross-sectional view of an eFuse device illustrating the principle of the reverse stress in the electromigration process. FIG. 5A is a schematic diagram illustrating the programming principle of the eFuse device according to the present invention. FIG. 5B is another schematic diagram illustrating the programming principle of the eFuse device according to the present invention.

Referring to FIG. 4, in the electromigration process, electrons flow from the cathode to the anode, resulting in a drift of atoms from the cathode to the anode. Thus, a void is formed at the cathode end while there is an aggregation of metal atoms at the anode end. Accordingly, a mechanical compressive stress is formed at the anode end, resulting in a reversed migration process that reduces or even compensates the effective material flow towards the anode end.

Referring to FIG. 5A, the compressive stress layer on the anode applies tensile stress to the anode, and the tensile stress layer on the cathode applies compressive stress to the cathode. The tensile stress at the anode end can compensate the reverse stress (compressive back-stress) from the insulating dielectric layer. Thus, the stress at the anode end is significantly reduced (or may be considered as zero), atoms coming from the cathode can move easily, and void can be easily formed so that the programming time will be shortened with the same programming voltage and programming current.

Referring to FIG. 5B, the void is formed at the junction of the compressive stress and the tensile stress, the junction is located typically in the middle of the fuse link portion where compressive stress and tensile stress interact. The reason is that the compressive stress in the cathode side can slow down the motion of atoms from the cathode to the middle of the fuse link portion. Thus, the effective length of the fuse link portion is reduced, thereby facilitating the programming of the eFuse device, i.e., it requires either a lower programming current or a shorter programming time.

The above description describes that the programming performance of an eFuse device according to the present invention can be improved by having a compressive stress layer covering the anode and a tensile stress layer covering the cathode, i.e., the eFuse device of the present invention may be programmed with a reduced programming voltage or a shorter programming time.

In summary, embodiments of the present invention provide an eFuse device that has a compressive stress layer on the anode and a tensile stress layer on the cathode. The thus formed eFuse device has a faster programming speed with respect to conventional eFuse devices.

### Embodiment 2

Embodiments of the present invention provide an integrated circuit that includes an electrically programmable fuse according to the eFuse device described in embodiment 1 above. The integrated circuit may be a digital integrated circuit, an analog integrated circuit, or a mixed-signal integrated circuit including digital and analog circuits.

In the embodiment, the integrated circuit comprises an electrically programmable fuse device. The electrically programmable fuse device includes an anode, a cathode, a fuse link portion connecting the anode to the cathode, a compressive stress layer disposed on the anode, and a tensile stress layer disposed on the cathode.

In the embodiment, because the electrically programmable fuse device of the integrated circuit has a fast programming speed, the integrated circuit thus, has the same advantages and benefits of fast programming speed as the electrically programmable fuse device.

### Embodiment 3

Embodiments of the present invention provide an electronic device including an integrated circuit and an electronic component connected to the integrated circuit. The integrated circuit can be the integrated circuit of embodiment 2 described above. The electronic component can be a discrete device, an integrated circuit, or it can include multiple chips, and others.

In an embodiment, the electronic device may include an integrated circuit that contains an electrically programmable fuse device. The electrically programmable fuse device may include an anode, a cathode, a fuse link portion connecting the anode to the cathode, a compressive stress layer disposed on the anode, and a tensile stress layer disposed on the cathode

In accordance with the present invention, the electronic device may be a mobile phone, a laptop computer, a netbook, a tablet PC, a game console, a TV receiver, a DVD player, a GPS device, a camera, a voice recorder, MP3, MP4, PSP players, and other semiconductor devices including intermediate products and electronic components that may include the above-described electrically programmable fuse device for faster programming speed.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments as well as other embodiments will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof

What is claimed is:

1. An electrically programmable fuse device comprising:
an anode;
a cathode,
a fuse link connecting the anode and the cathode;
a compressive stress layer on the anode; and
a tensile stress layer on the cathode.

2. The electrically programmable fuse device of claim 1, wherein the compressive stress layer and the tensile stress layer extend on a surface of the fuse link.

3. The electrically programmable fuse device of claim 2, wherein the compressive stress layer and the tensile stress layer are adjacent to each other.

4. The electrically programmable fuse device of claim 1, wherein the compressive stress layer comprises a compressive stress silicon nitride material, and the tensile stress layer comprises a tensile stress silicon nitride material.

5. The electrically programmable fuse device of claim 1, wherein the compressive stress layer and the tensile stress layer are an etch stop layer for forming a contact hole.

6. The electrically programmable fuse device of claim 1, wherein the anode, the cathode, and the fuse link each comprise a polysilicon layer and a silicide layer on the polysilicon layer.

7. The electrically programmable fuse device of claim 6, wherein the silicide layer comprises at least one of nickel silicide, titanium silicide, cobalt silicide, tantalum silicide, and platinum silicide.

8. The electrically programmable fuse device of claim 1, wherein the anode and the cathode have a same shape.

9. The electrically programmable fuse device of claim 8, wherein the shape is a rectangle.

10. The electrically programmable fuse device of claim 8, wherein the shape comprises a rectangle and a trapezoid.

11. The electrically programmable fuse device of claim 10, wherein the trapezoid is an isosceles trapezoid.

12. The electrically programmable fuse device of claim 8, wherein the shape is a polygon having a portion tapering toward the fuse link.

13. The electrically programmable fuse device of claim 1, wherein the compressive stress layer applies tensile stress to the anode, and the tensile stress layer applies compressive stress to the cathode.

14. The electrically programmable fuse device of claim 13, wherein the tensile stress compensates the compressive reverse stress from a dielectric layer.

15. The electrically programmable fuse device of claim 13, wherein the compressive stress slows down atom migration from the cathode toward a middle of the fuse link.

16. An integrated circuit comprising an electrically programmable fuse device, wherein the electrically programmable fuse device comprises:
an anode;
a cathode,
a fuse link connecting the anode and the cathode;
a compressive stress layer on the anode; and
a tensile stress layer on the cathode.

17. An electronic device comprising an integrated circuit and an electronic component coupled to the integrated circuit, wherein the integrated circuit comprises an electrically programmable fuse device comprising
an anode;
a cathode,
a fuse link connecting the anode and the cathode;
a compressive stress layer on the anode; and
a tensile stress layer on the cathode.
